(19) United States
(12) Patent Application Publication
(10) Pub. No.: US 2025/0081746 A1
(43) Pub. Date: Mar. 6, 2025

(54) LIGHT EMITTING DISPLAY DEVICE

(71) Applicant: LG Display Co., Ltd., Seoul (KR)

(72) Inventors: Jaehyung YU, Paju-si (KR); Beomgon JO, Paju-si (KR)

(73) Assignee: LG Display Co., Ltd., Seoul (KR)

(21) Appl. No.: 18/675,501

(22) Filed: May 28, 2024

(30) Foreign Application Priority Data
Aug. 29, 2023 (KR) 10-2023-0113686

(51) Int. Cl. H10K 59/122; H10K 59/80

(52) U.S. Cl. CPC H10K 59/122; H10K 59/80515

(57) ABSTRACT

A light emitting display device according to one or more examples may include: a lower anode electrode on a substrate; a first pixel defining layer covering middle areas of the lower anode electrode and exposing circumferential areas of the lower anode electrode; an anode electrode covering a top surface of the first pixel defining layer and connecting to the circumferential areas of the lower anode electrode; a second pixel defining layer exposing a top surface of the anode electrode and covering side-wall surface of the anode electrode; a trench formed at the second pixel defining layer and disposed around the anode electrode; an emission layer on the anode electrode; and a cathode electrode on the emission layer.

### CROSS-REFERENCE TO RELATED APPLICATIONS

This application claims the benefit of and priority to Korean Patent Application No. 10-2023-0113686 filed on Aug. 29, 2023, the entirety of which is incorporated herein by reference for all purposes as if fully set forth herein.

### BACKGROUND

### 1. Technical Field

The present disclosure relates to an apparatus, and particularly to, for example, without limitation, a light emitting display device.

### 2. Discussion of the Related Art

In a light emitting display device, a structure for solving the short circuit problem between pixels by arranging banks around the pixels has been proposed. However, for an ultra-high resolution of, for example, 4,000 PPI (pixel per inch; 4K PPI) or higher, it is difficult to achieve the high resolution structure due to banks. For the case of ultra-high resolution, leakage current may occur because the distance between pixels is close. Therefore, there is a need to develop a structure for a light emitting display device, such as an ultra-high resolution light emitting display device, that can eliminate horizontal leakage current when the pixel spacing becomes narrower.

The description of the related art should not be assumed to be prior art merely because it is mentioned in or associated with this section. The description of the related art includes information that describes one or more aspects of the subject technology, and the description in this section does not limit the invention.

### SUMMARY

The inventors of the present disclosure have recognized the problems and disadvantages of the related art and have performed extensive research and experiments. The inventors of the present disclosure have thus invented a display device that substantially obviate one or more problems due to limitations and disadvantages of the related art.

One or more aspects of the present disclosure can solve, among others, one or more of the problems described above and provide an ultra-high-resolution light emitting display device of 4K or higher with improved display quality.

One or more example embodiments of the present disclosure may be directed to provide an ultra-high-resolution light emitting display device that solves the short-circuit problem between neighboring pixels without using banks.

One or more example embodiments of the present disclosure may be directed to provide a light emitting display device with a high aperture ratio and excellent luminous efficiency even in a 4K or more ultra-high-resolution structure with a small pixel size.

One or more example embodiments of the present disclosure may be directed to provide a light emitting display device that implements ultra-high resolution and prevents horizontal leakage current between pixels even when the gap between neighboring pixels becomes narrow.

In order to accomplish these and other advantages and aspects of the present disclosure, a light emitting display device according to one or more example embodiments of the present disclosure comprises: a lower anode electrode on a substrate; a first pixel defining layer covering middle areas of the lower anode electrode and exposing circumferential areas of the lower anode electrode; an anode electrode covering a top surface of the first pixel defining layer and connecting to the circumferential areas of the lower anode electrode; a second pixel defining layer exposing a top surface of the anode electrode and covering side-wall surface of the anode electrode; a trench formed at the second pixel defining layer and disposed around the anode electrode; an emission layer on the anode electrode; and a cathode electrode on the emission layer.

In one or more example embodiments, a top surface of the second pixel defining layer is disposed at a same leveled plane as the top surface of the anode electrode.

In one or more example embodiments, the light emitting display device further comprises: an emission area defined by portions of the anode electrode, the portions of the anode electrode being not covered by the second pixel defining layer.

In one or more example embodiments, an end portion of the anode electrode is in contact with an end portion of the lower anode electrode.

In one or more example embodiments, end portions of the anode electrode are bent to be in surface contact with circumferential top surfaces of the lower anode electrode.

In one or more example embodiments, a top surface of the second pixel defining layer is disposed at a plane lower than the top surface of the anode electrode.

In one or more example embodiments, a top surface of the second pixel defining layer is disposed at a plane same as the top surface of the anode electrode.

In one or more example embodiments, a cross-sectional shape of the first pixel defining layer is a rectangular shape including: a bottom surface being in surface contact with the lower anode electrode; and the top surface and a side-wall surface being in surface contact with the anode electrode.

In one or more example embodiments, the first pixel defining layer includes an upper edge corner, and the upper edge corner has a curved shape where the top surface and the side-wall surface of the first pixel defining layer meet.

In one or more example embodiments, the anode electrode is deposited (or disposed) on the first pixel defining layer, following the curved shape at the upper edge corner of the first pixel defining layer.

Furthermore, a light emitting display device according to one or more example embodiments of the present disclosure comprises: a plurality of pixels on a substrate; a plurality of anode electrodes, each of the plurality of anode electrodes disposed at a corresponding one of the plurality of pixels; a first pixel defining layer between the plurality of anode electrodes; a trench formed at a middle portion of the first pixel defining layer; an emission layer deposited (or disposed) on the plurality of anode electrodes and the first pixel defining layer, the emission layer being separated between the plurality of anode electrodes by the trench; and a cathode electrode disposed on the emission layer, the cathode electrode extending over all of the plurality of pixels and extending over the trench.

In one or more example embodiments, a top surface of the first pixel defining layer is disposed at a plane same as a top surface of an anode electrode of the plurality of anode electrodes.

In one or more example embodiments, the light emitting display device further comprises: an emission area defined by an area of an anode electrode of the plurality of anode electrodes, the area being not covered by the first pixel defining layer.

In one or more example embodiments, a top surface of the first pixel defining layer is disposed at a plane with a height lower than a top surface of an anode electrode of the plurality of anode electrodes by a thickness of the anode electrode.

In one or more example embodiments, each of the plurality of anode electrodes includes: a lower anode electrode; a second pixel defining layer covering middle areas of the lower anode electrode and exposing circumferential areas of the lower anode electrode; and an upper anode electrode covering a top surface of the second pixel defining layer and being in connection with the circumferential areas of the lower anode electrode exposed by the second pixel defining layer.

In one or more example embodiments, a cross-sectional shape of the second pixel defining layer is a rectangular shape including: a bottom surface being in surface contact with the lower anode electrode; and the top surface and a side-wall surface being in surface contact with the upper anode electrode.

In one or more example embodiments, the second pixel defining layer includes an upper edge corner, and the upper edge corner has a curved shape where the top surface and the side-wall surface of the first pixel defining layer meet.

In one or more example embodiments, the upper anode electrode is deposited (or disposed) on the second pixel defining layer, following the curved shape at the upper edge corner of the second pixel defining layer.

In one or more example embodiments, the second pixel defining layer disposed at a first pixel of the plurality of pixels has a height different from a height of the second pixel defining layer disposed at another pixel of the plurality of pixels neighboring the first pixel.

A light emitting display device according to one or more example embodiments of the present disclosure comprises: a lower anode electrode disposed on a substrate, the lower anode electrode having a central portion and a circumferential portion; an upper anode electrode disposed on the lower anode electrode, the upper anode electrode being in contact with the circumferential portion of the lower anode electrode; a first pixel defining layer disposed between the lower anode electrode and the upper anode electrode, the first pixel defining layer located at least at the central portion of the lower anode electrode without covering the circumferential portion of the lower anode electrode; an emission layer on the upper anode electrode; and a cathode electrode on the emission layer.

In one or more example embodiments, the light emitting display device further comprises: a second pixel defining layer surrounding the upper anode electrode; and a trench surrounding the upper anode electrode.

The light emitting display device according to one or more example embodiments of the present disclosure has an ultra-high-resolution structure of 4K or higher that does not cause short-circuit problems between pixels without bank.

The light emitting display device according to one or more example embodiments of the present disclosure has a structure in which the lateral leakage current is not occurred by including a trench for blocking or preventing leakage current between neighboring pixels.

Without banks for covering the circumferential areas of the pixel electrode, the light emitting display device according to one or more example embodiments of the present disclosure may use the entire area of the pixel electrode as the light emitting area, and have a structure with a high aperture ratio and excellent luminous efficiency.

The light emitting display device according to one or more example embodiments of the present disclosure does not cause short circuits between pixels and does not generate leakage current between pixels, so low-power driving may be possible.

Other apparatuses, methods, features and advantages are described herein or will be apparent to one with skill in the art upon examination of the drawings and detailed description herein. It is intended that all such apparatuses, methods, features and advantages be included within this description, be within the scope of the present disclosure, and be protected by the following claims. Nothing in this section should be taken as a limitation on the claims. Further aspects and advantages are discussed below in conjunction with embodiments of the disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure, and together with the description serve to explain principles and examples of the disclosure.

FIG. 1 is a plane view illustrating a schematic structure of a light emitting display device according to one or more example embodiments of the present disclosure.

FIG. 2 is an example of a circuit diagram illustrating a structure of one pixel disposed in the display area shown in FIG. 1.

FIG. 3 is an enlarged plan view illustrating a structure of four pixels sequentially disposed on the thin film transistor substrate of the light emitting display device according to one or more example embodiments of the present disclosure.

FIG. 4 is a cross-sectional view along line I-I′ in FIG. 3, for illustrating a structure of a light emitting display device according to a first example embodiment of the present disclosure.

FIG. 5 is a cross-sectional view, along line I-I′ of FIG. 3, for illustrating a structure of a light emitting display device according to a second example embodiment of the present disclosure.

FIG. 6 is a cross-sectional view, along line I-I′ of FIG. 3, for illustrating a structure of a light emitting display device according to a third example embodiment of the present disclosure.

FIG. 7 is a cross-sectional view, along line I-I′ of FIG. 3, for illustrating a structure of a light emitting display device according to a fourth example embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Reference is now made in detail to embodiments of the present disclosure, examples of which may be illustrated in the accompanying drawings. In the following description, when a detailed description of well-known methods, functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete to assist those skilled in the art to understand the inventive concepts without limiting the protected scope of the present disclosure.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings, are merely examples, and thus, the present disclosure is not limited to the illustrated details. It is, however, noted that the relative dimensions of the components illustrated in the drawings are part of the present disclosure.

When the term “comprise,” “have,” “include,” “contain,” “constitute,” “made of,” “formed of,” “composed of,” or the like is used with respect to one or more elements (e.g., layers, films, regions, components, sections, members, parts, regions, areas, portions, steps, operations, and/or the like), one or more other elements may be added unless a term such as “only” or the like is used. The terms used in the present disclosure are merely used in order to describe particular example embodiments, and are not intended to limit the scope of the present disclosure. The terms of a singular form may include plural forms unless the context clearly indicates otherwise. The word “exemplary” is used to mean serving as an example or illustration. Embodiments are example embodiments. Aspects are example aspects. “Embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

When a positional relationship between two elements (e.g., layers, films, regions, components, sections, members, parts, regions, areas, portions, and/or the like) are described using any of the terms such as “on,” “on a top of,” “upon,” “on top of,” “over,” “under,” “above,” “upper,” “below,” “lower,” “beneath,” “near,” “close to,” “adjacent to,” “beside,” “next to,” “at or on a side of,” and/or the like indicating a position or location, one or more other elements may be located between the two elements unless a more limiting term, such as “immediate(ly),” “direct(ly),” or “close(ly),” is used. For example, when an element and another element are described using any of the foregoing terms, this description should be construed as including a case in which the elements contact each other directly as well as a case in which one or more additional elements are disposed or interposed therebetween. Furthermore, the spatially relative terms such as the foregoing terms as well as other terms such as “front,” “rear,” “back,” “left,” “right,” “top,” “bottom,” “downward,” “upward,” “up,” “down,” “column,” “row,” “vertical,” “horizontal,” “diagonal,” and the like refer to an arbitrary frame of reference. For example, these terms may be used for an example understanding of a relative relationship between elements, including any correlation as shown in the drawings. However, embodiments of the disclosure are not limited thereby or thereto. The spatially relative terms are to be understood as terms including different orientations of the elements in use or in operation in addition to the orientation depicted in the drawings or described herein. For example, where a lower element or an element positioned under another element is overturned, then the element may be termed as an upper element or an element positioned above another element. Thus, for example, the term “under” or “beneath” may encompass, in meaning, the term “above” or “over.” An example term “below” or the like, can include all directions, including directions of “below,” “above” and diagonal directions. Likewise, an example term “above,” “on” or the like can include all directions, including directions of “above,” “on,” “below” and diagonal directions.

In describing a temporal relationship, when the temporal order is described as, for example, “after,” “subsequent,” “next,” “before,” “preceding,” “prior to,” or the like, a case that is not consecutive or not sequential may be included and thus one or more other events may occur therebetween, unless a more limiting term, such as “just,” “immediate(ly),” or “direct(ly),” is used.

It is understood that, although the terms “first,” “second,” and the like may be used herein to describe various elements (e.g., layers, films, regions, components, sections, members, parts, regions, areas, portions, steps, operations, and/or the like), these elements should not be limited by these terms, for example, to any particular order, precedence, or number of elements. These terms are used only to distinguish one element from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

For the expression that an element (e.g., layer, film, region, component, section, member, part, region, area, portion, or the like) is “connected,” “coupled,” “attached,” “adhered,” “linked,” or the like to another element, the element can not only be directly connected, coupled, attached, adhered, linked, or the like to another element, but also be indirectly connected, coupled, attached, adhered, linked, or the like to another element with one or more intervening elements disposed or interposed between the elements, unless otherwise specified.

For the expression that an element (e.g., layer, film, region, component, section, member, part, region, area, portion, or the like) “contacts,” “overlaps,” or the like with another element, the element can not only directly contact, overlap, or the like with another element, but also indirectly contact, overlap, or the like with another element with one or more intervening elements disposed or interposed between the elements, unless otherwise specified.

The phase that an element (e.g., layer, film, region, component, section, member, part, region, area, portion, or the like) is “provided,” “disposed,” “connected,” “coupled,” or the like in, on, with or to another element may be understood, for example, as that at least a portion of the element is provided, disposed, connected, coupled, or the like in, on, with or to at least a portion of another element. The phrase “through” may be understood, for example, to be at least partially through or entirely through. The phase that an element (e.g., layer, film, region, component, section, member, part, region, area, portion, or the like) “contacts,” “overlaps,” or the like with another element may be understood, for example, as that at least a portion of the element contacts, overlaps, or the like with a least a portion of another element.

The terms such as a “line” or “direction” should not be interpreted only based on a geometrical relationship in which the respective lines or directions are parallel, perpendicular, diagonal, or slanted with respect to each other, and may be meant as lines or directions having wider directivities within the range within which the components of the present disclosure may operate functionally.

The term “at least one” should be understood as including any and all combinations of one or more of the associated listed items. For example, each of the phrases “at least one of a first item, a second item, or a third item” and “at least one of a first item, a second item, and a third item” may represent (i) a combination of items provided by two or more of the first item, the second item, and the third item or (ii) only one of the first item, the second item, or the third item. Further, at least one of a plurality of elements can represent (i) one element of the plurality of elements, (ii) some elements of the plurality of elements, or (iii) all elements of the plurality of elements. Further, “at least some,” “some,” “some elements,” “a portion,” “portions,” “at least a portion,” “at least portions,” “a part,” “at least a part,” “parts,” “at least parts,” “one or more,” or the like of the plurality of elements can represent (i) one element of the plurality of elements, (ii) a part of the plurality of elements, (iii) parts of the plurality of elements, (iv) multiple elements of the plurality of elements, or (v) all of the plurality of elements. Moreover, at least a portion (or a part) of an element can represent (i) a portion (or a part) of the element, (ii) one or more portions (or parts) of the element, or (iii) the element, or the entirety of the element. A phrase that a plurality of first elements are connected to a plurality of second elements may describe, for example, that at least a part (or one or more first elements) of a plurality of first elements are connected to at least a part (or one or more second elements) of a plurality of second elements.

The expression of a first element, a second elements “and/or” a third element should be understood as one of the first, second and third elements or as any or all combinations of the first, second and third elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element (e.g., layer, film, region, component, section, member, part, region, area, portion, or the like) is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

Features of various embodiments of the present disclosure may be partially or entirely coupled to or combined with each other, may be technically associated with each other, and may be variously operated, linked or driven together in various ways. Embodiments of the present disclosure may be implemented or carried out independently of each other or may be implemented or carried out together in a co-dependent or related relationship. In one or more aspects, the components of each apparatus and device according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example embodiments of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

FIG. 1 is a plane view illustrating a schematic structure of a light emitting display device according to one or more example embodiments of the present disclosure. In FIG. 1, X-axis refers to the direction parallel to the scan line, Y-axis refers to the direction of the data line, and Z-axis refers to the height direction of the display device.

Referring to FIG. 1, the electroluminescence display comprises a substrate 110, a gate (or scan) driver 200, a pad portion 300, a source driving IC (Integrated Circuit) 410, a flexible circuit film 430, a circuit board 450, and a timing controller 500.

The substrate 110 may include an electrically insulating material or a flexible material. The substrate 110 may be made of a glass, a metal or a plastic, but it is not limited thereto. When the light emitting display device is a flexible display, the substrate 110 may be made of the flexible material such as plastic. For example, the substrate 110 may include a transparent polyimide material.

The substrate 110 may include a display area AA and a non-display area NDA. The display area AA, which is an area for representing the video images, may be defined as the majority middle area of the substrate 110, but it is not limited thereto. In the display area AA, a plurality of scan lines (or gate lines), a plurality of data lines and a plurality of pixels may be disposed. Each of pixels may include a plurality of sub pixels. Each of sub pixels may include a scan line SL running parallel to X-axis and a data line DL running parallel to Y-axis.

The non-display area NDA, which is an area not representing the video images, may be defined at the circumference areas of the substrate 110 surrounding all or some of the display area AA. In the non-display area NDA, the gate driver 200 and the pad portion 300 may be formed or disposed.

The gate driver 200 may supply the scan (or gate) signals to the scan lines according to the gate control signal received from the timing controller 500 through the pad portion 300. The gate driver 200 may be formed at the non-display area NDA at any one outside of the display area DA on the substrate 110, as a GIP (Gate driver In Panel) type. GIP type means that the gate driver 200 is directly formed on the substrate 110. For example, the gate driver 200 may be configured with shift registers. In the GIP type, the transistors for shift registers of the gate driver 200 are directly formed on the upper surface of the substrate 110.

The pad portion 300 may be disposed in the non-display area NDA at one side edge of the display area AA of the substrate 110. The pad portion 300 may include data pads connected to each of the data lines, driving current pads connected to the driving current lines, a high-potential pad receiving a high potential voltage, and a low-potential pad receiving a low potential voltage.

The source driving IC 410 may receive the digital video data and the source control signal from the timing controller 500. The source driving IC 410 may convert the digital video data into the analog data voltages according to the source control signal and then supply that to the data lines. When the source driving IC 410 is made as a chip type, it may be installed on the flexible circuit film 430 as a COF (Chip On Film) or COP (Chip On Plastic) type.

The flexible circuit film 430 may include a plurality of first link lines connecting the pad portion 300 to the source driving IC 410, and a plurality of second link lines connecting the pad portion 300 to the circuit board 450. The flexible circuit film 430 may be attached on the pad portion 300 using an anisotropic conducting film, so that the pad portion 300 may be connected to the first link lines of the flexible circuit film 430.

The circuit board 450 may be attached to the flexible circuit film 430. The circuit board 450 may include a plurality of circuits implemented as the driving chips. For example, the circuit board 450 may be a printed circuit board or a flexible printed circuit board.

The timing controller 500 may receive the digital video data and the timing signal from an external system board through the line cables of the circuit board 450. The timing controller 500 may generate a gate control signal for controlling the operation timing of the gate driver 200 and a source control signal for controlling the source driving IC 410, based on the timing signal. The timing controller 500 may supply the gate control signal to the gate driver 200 and supply the source control signal to the source driving IC 410. Depending on the product types, the timing controller 500 may be integrated with the source driving IC 410 into one driving chip and may be mounted on the substrate 110 to be connected to the pad unit 300.

### One or More Example Embodiments and First Example Embodiment

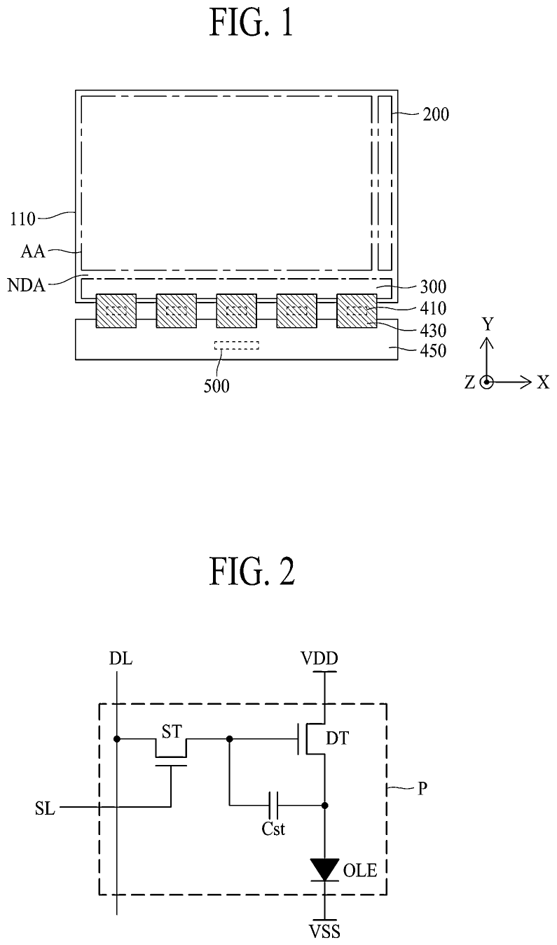

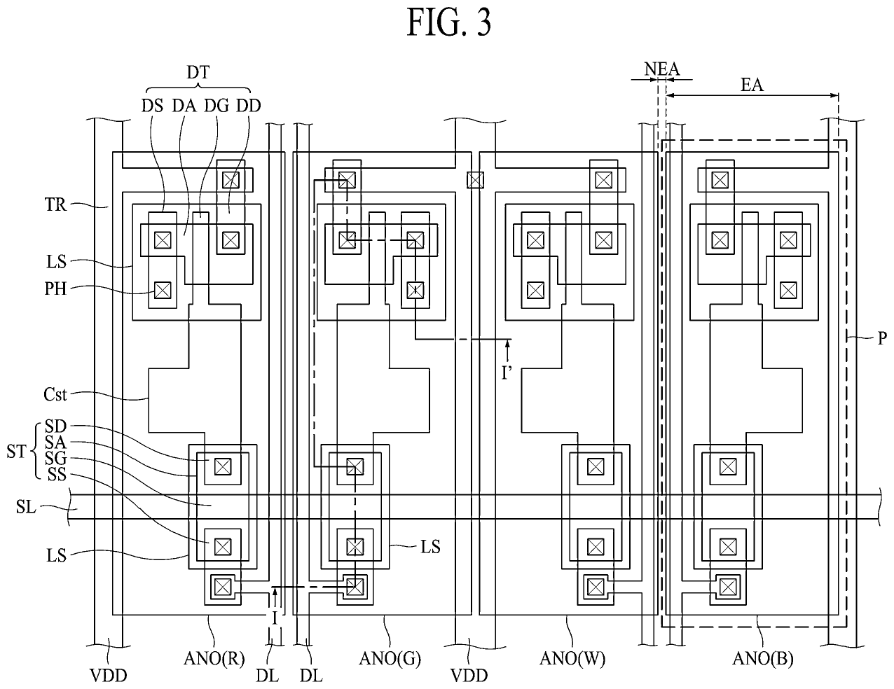

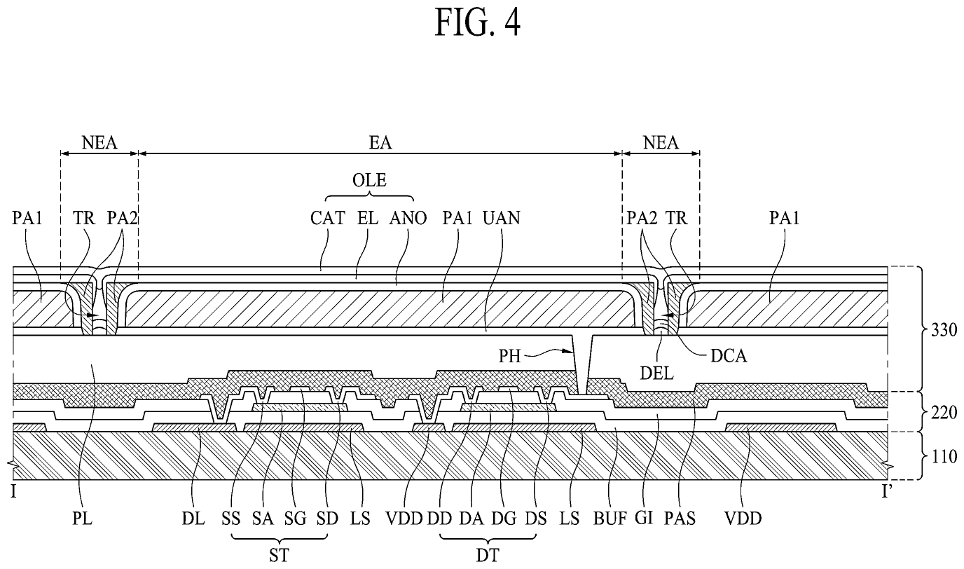

Hereinafter, referring to FIGS. 2 to 4, a detailed structure of a light emitting display device according to one or more example embodiments and a first example embodiment of the present disclosure will be explained. FIG. 2 is a circuit diagram illustrating a structure of one pixel disposed in a display area according to one or more example embodiments of the present disclosure. FIG. 3 is an enlarged plan view illustrating a structure of four pixels sequentially disposed on the thin film transistor substrate of the light emitting display device according to one or more example embodiments of the present disclosure. FIG. 4 is a cross-sectional view along line I-I′ in FIG. 3, for illustrating a structure of a light emitting display device according to a first example embodiment of the present disclosure. In convenience, FIG. 4 shows the structure of three consecutive pixels P among the four pixels P arranged in succession shown in FIG. 3.

Referring to FIGS. 2 to 4, each pixel (or sub pixel) P of the light emitting display according to one or more example embodiments of the present disclosure may be defined by a scan line SL, a data line DL and a driving current line VDD. Each pixel P of the light emitting display may include a switching thin film transistor ST, a driving thin film transistor DT, a light emitting diode OLE and a storage capacitance Cst. The driving current line VDD may be supplied with a high-level voltage for driving the light emitting diode OLE.

A switching thin film transistor ST and a driving thin film transistor DT may be formed on a substrate 110. For example, the switching thin film transistor ST may be configured to be connected to the scan line SL and the data line DL crossing with the scan line SL. The switching thin film transistor ST may include a gate electrode SG, a semiconductor layer SA, a source electrode SS and a drain electrode SD. The gate electrode SG may be a portion of the scan line SL. The semiconductor layer SA may be disposed as crossing the gate electrode SG. The overlapped portion of the semiconductor layer SA with the gate electrode SG may be defined as the channel area. The source electrode SS may be branched from or connected to the data line DL, and the drain electrode SD may be connected to the driving thin film transistor DT. The source electrode SS may be one side of the semiconductor layer SA from the channel area, and the drain electrode SD may be the other side of the semiconductor layer SA. By supplying the data signal to the driving thin film transistor DT, the switching thin film transistor ST may play a role of selecting a pixel P which would be driven.

The driving thin film transistor DT may play a role of driving the light diode OLE of the selected pixel P by the switching thin film transistor ST. The driving thin film transistor DT may include a gate electrode DG, a semiconductor layer DA, a source electrode DS and a drain electrode DD. The gate electrode DG of the driving thin film transistor DT may be connected to the drain electrode SD of the switching thin film transistor ST. For example, the gate electrode DG of the driving thin film transistor DT may be extended form the drain electrode SD of the switching thin film transistor ST. In the driving thin film transistor DT, the drain electrode DD may be branched from or connected to the driving current line VDD, further, the source electrode DS may be connected to the anode electrode (or pixel electrode) ANO of the light emitting diode (or light emitting element) OLE. The semiconductor layer DA may be disposed as crossing over the gate electrode DG. In the semiconductor layer DA, the overlapped portion with the gate electrode DG may be defined as a channel area. The source electrode DS may be connected at one side of the semiconductor layer DA around the channel area, and the drain electrode DD is connected to the other side of the semiconductor layer DA. A storage capacitance Cst may be disposed between the gate electrode DG of the driving thin film transistor DT and the anode electrode ANO of the light emitting diode OLE.

The light emitting diode OLE may generate light according to the current controlled by the driving thin film transistor DT. The driving thin film transistor DT may control the amount of current flowing from the driving current line VDD to the light emitting diode OLE according to the voltage difference between the gate electrode DG and the source electrode DS.

The light emitting diode OLE may include an anode electrode ANO, an emission layer EL, and a cathode electrode CAT. The light emitting diode OLE may emit light according to the current controlled by the driving thin film transistor DT. In other words, the light emitting diode OLE may provide an image by emitting light according to the current controlled by the driving thin film transistor DT. The anode electrode ANO of the light emitting diode OLE may be connected to the source electrode DS of the driving thin film transistor DT. The cathode electrode CAT (or, common electrode) may be supplied with the low-potential voltage through a low-power line VSS. Therefore, the light emitting diode OLE may be driven by the electric current flown from the driving current line VDD to the low power line VSS controlled by the driving thin film transistor DT.

A plurality of pixels P may be arrayed on the substrate 110. For example, along the horizontal direction, a red pixel R, a green pixel G, a white pixel W and a blue pixel B may be sequentially arrayed and disposed. The combination of the red pixel R, the green pixel G, the white pixel W and the blue pixel B may configure one pixel. Otherwise, each of the red pixel R, the green pixel G, the white pixel W and the blue pixel B may be referred to as a sub-pixel. These sub-pixels are combined to form one pixel. In another case, the red pixel, the green pixel and the blue pixel may be sequentially arrayed along the horizontal direction. The red pixel, the green pixel and the blue pixel may form a unit pixel. FIG. 3 shows that four pixels P are sequentially arrayed along the horizontal direction to form one unit pixel.

Referring to FIG. 4, a light emitting display device according to the first example embodiment of the present disclosure will be explained. The light emitting display device according to the first example embodiment may include a substrate 110, a driving element layer 220 and a light emitting element layer 330. The driving element layer 220 may include a plurality of thin layers formed on the substrate 110. The driving element layer 220 may include a switching thin film transistor ST and a driving thin film transistor DT.

On the substrate 110, a data line DL, a driving current line VDD and a light shielding layer LS may be formed. The light shielding layer LS may be disposed in an island shape spaced apart from the data line DL and the driving current ling VDD by a predetermined distance and overlapping the semiconductor layers SA and DA.

A buffer layer BUF is deposited (or disposed) on the entire surface of the substrate 110, covering the data line DL and the driving current line VDD. On the buffer layer BUF, a switching thin film transistor ST and a driving thin film transistor DT are formed.

On the buffer layer BUF, the semiconductor layer SA of the switching thin film transistor ST and the semiconductor layer DA of the driving thin film transistor DT are formed. The switching thin film transistor ST and the driving thin film transistor DT are formed on the buffer layer BUF. In one or more aspects, it is preferable that the channel areas in the semiconductor layers SA and DA overlap with the light shielding layer LS.

A gate insulating layer GI is deposited (or disposed) on the substrate 110, covering the semiconductor layers SA and DA. A gate electrode SG overlapping with the semiconductor layer SA of the switching thin film transistor ST and the gate electrode DG overlapping with the semiconductor layer DA of the driving thin film transistor DT are formed on the gate insulating layer GI. In addition, at both sides of the gate electrode SG of the switching thin film transistor ST, a source electrode SS contacting one side of the semiconductor layer SA while being spaced apart from the gate electrode SG, and a drain electrode SD contacting the other side of the semiconductor layer SA are formed. Further, at both sides of the gate electrode DG of the driving thin film transistor DT, a source electrode DS contacting one side of the semiconductor layer DA while being spaced apart from the gate electrode DG, and a drain electrode DD contacting the other side of the semiconductor layer DA are formed.

The gate electrodes SG and DG and the source-drain electrodes SS-SD and DS-DD are formed on the same layer, but are spatially and electrically separated from each other. The source electrode SS of the switching thin film transistor ST may be connected to the data line DL via a contact hole penetrating the gate insulating layer GI. Further, the drain electrode DD of the driving thin film transistor DT may be connected to the driving current line VDD via another contact hole penetrating the gate insulating layer.

A passivation layer PAS is deposited (or disposed) on the substrate 110, covering the thin film transistors ST and DT. The passivation layer PAS may be made of an inorganic material such as silicon oxide or silicon nitride.

The light emitting element layer 330 is formed on the driving element layer 220. The light emitting element layer 330 may include a light emitting diode OLE. Before forming the light emitting diode OLE, a planarization layer PL may be disposed on the passivation layer PAS. The planarization layer PL is a thin film layer used for flattening the uneven surface condition of the substrate 110 on which the switching thin film transistor ST and the driving thin film transistor DT are formed. To equalize the height difference, the planarization layer PL may be formed of an organic material. A pixel contact hole PH exposing a part of the source electrode DS of the driving thin film transistor DT is formed in the passivation layer PAS and the planarization layer PL.

A lower anode electrode UAN may be formed on the upper surface of the planarization layer PL. The lower anode electrode UAN may be connected to the source electrode DS of the driving thin film transistor DT via a pixel contact hole PH. Since one or more example embodiments of the present disclosure are related to a top-emission mode, the lower anode electrode UAN may be formed of a metal material with excellent light reflectance.

A first pixel defining layer PA1 may be formed on the lower anode electrode UAN. In one or more aspects, the first pixel defining layer PA1 is preferably formed after applying an insulating material and then patterned to cover the central portion of the lower anode electrode UAN and expose (or not cover) the circumferential areas of the lower anode electrode UAN. In one or more aspects, it is preferable that the exposed surface area of the lower anode electrode UAN exposed by the first pixel defining layer PA1 is as small as possible. In one or more aspects, it is preferable that the minimum exposed surface area may be configured to have a width corresponding to the thickness of the anode electrode ANO to be formed later.

An anode electrode ANO is formed on the first pixel defining layer PA1. In one or more aspects, it is preferable that the anode electrode ANO is physically and electrically connected to the lower anode electrode UAN. As the lower anode electrode UAN is an electrode that reflects the light provided from the light emitting diode OLE disposed at upper direction, the anode electrode ANO may be a transparent electrode for transmitting the light provided from the light emitting diode OLE. Therefore, the anode electrode ANO may be made of a transparent conductive material. For example, the anode electrode ANO may include indium-tin oxide (ITO) or indium-zinc oxide (IZO). Otherwise, the anode electrode ANO may be made of half-transparent material. For example, the anode electrode ANO may have a structure in which indium-tin oxide and silver (Ag) are stacked, wherein silver (Ag) may be formed thinly with a thickness of 300 Å or less.

The anode electrode ANO may be deposited (or disposed), covering the upper surface of the first pixel defining layer PA1. In detail, for the first pixel defining layer PA1, the bottom surface may be in contact with the lower anode electrode UAN, and the side surface and top surface may be exposed. The anode electrode ANO may be deposited (or disposed) as being in contact with the side surface and the top surface of the first pixel defining layer PA1. In addition, the anode electrode ANO may be deposited (or disposed) on the lower anode electrode UAN exposed by the first pixel defining layer PA1. For example, as shown in FIG. 4, the cross-sectional shape of the anode electrode ANO may have a ‘cap (∩)’ shape.

A second pixel defining layer PA2 may be formed on the surface of the substrate 110 having the anode electrode ANO. In one or more aspects, it is preferable that the second pixel defining layer PA2 may fill in the space between two neighboring anode electrodes ANO. The top surface of the second pixel defining layer PA2 may form the same leveled plane as the top surface of the anode electrode ANO. Therefore, the second pixel defining layer PA2 may expose (or not cover) the top surface of the anode electrode ANO, and cover the side-wall surfaces of the anode electrode ANO. The top surface portion of the anode electrode ANO exposed by the second pixel defining layer PA2 may be defined as an emission area EA.

A trench TR may be formed at the central area of the second pixel defining layer PA2. In a plan view, as the second pixel defining layer PA2 is arranged to surround the anode electrode ANO, in one or more aspects, it is preferable that the trench TR is also arranged to surround the anode electrode ANO. In some cases, the trench TR may be disposed between two neighboring anode electrodes ANO along X-axis (or lateral direction).

The anode electrode ANO has a structure in which substantially the entire top surface is exposed by the second pixel defining layer PA2. That is, the area not having the second pixel defining layer PA2 and trench TR may be defined as the emission area EA. The area where the second pixel defining layer PA2 and trench TR are formed may be defined as a non-emission area NEA.

An emission layer EL is disposed on the anode electrode ANO. The emission layer EL may be deposited (or disposed) on the entire display area AA of the substrate 110, covering the anode electrode ANO. In particular, at the area where the trench TR is disposed, the emission layer EL may be partially deposited (or disposed) on the upper part of the removed side of the second pixel defining layer PA2 and the bottom of the trench TR, and may be separated between two neighboring anode electrodes ANO by the trench TR. Due to this separated structure of the emission layer EL, no leakage current occurs between two neighboring anode electrodes ANO.

For an example, the emission layer EL may include at least two emission parts for generating white light. In detail, the emission layer EL may include a first emission part and a second emission part vertically stacked for generating white light by mixing the first light from the first emission part and the second light from the second emission part.

For another example, the emission layer EL may include any one of a blue emission part, a green emission part, and a red emission part for generating light corresponding to a color set in each pixel. Further, the light emitting diode OLE may include a functional layer for improving light emitting efficiency and/or lifetime of the emission layer EL.

A cathode electrode CAT is deposited (or disposed) on the entire surface of the substrate 110 on which the emission layer is formed. The cathode electrode CAT is deposited (or disposed) to make surface contact with the emission layer EL. The cathode electrode CAT is formed over the entire substrate 110 to be commonly connected to the emission layer EL deposited (or disposed) in all pixels. The cathode electrode CAT is deposited (or disposed) across the trench TR whose spacing is narrowed by the depositing of the emission layer EL, so the cathode electrode CAT may have a sheet structure physically and electrically connected over the entire display area AA.

As the display device according to one or more example embodiments of the present disclosure is the top emission type, the cathode electrode CAT may include a transparent conductive material. For example, the cathode electrode CAT may be made of a transparent conductive material such as indium-tin-oxide (ITO) or indium-zinc-oxide (IZO). Alternatively, the cathode electrode CAT may include a half transparent material. For example, the cathode electrode CAT may have a structure in which indium-tin oxide, silver (Ag) and indium-tin oxide are sequentially stacked to form ITO/Ag/ITO. In this case, it is preferable that the cathode electrode CAT may be formed with a thin thickness less than 300 Å.

Inside space of the trench TR, a dummy emission layer DEL that is not connected to the emission layer EL may be stacked on the bottom surface. Further, a dummy cathode electrode DCA which is not connected to the cathode electrode CAT may be stacked on the dummy emission layer DEL.

From the cross-sectional structure of the first pixel defining layer PA1, the first pixel defining layer PA1 may have a rectangular shape or trapezoidal shape. In FIG. 4, the cross-sectional shape of the first pixel defining layer PA1 has a rectangular shape, but it is not limited thereto. The first pixel defining layer PA1 may have a trapezoidal shape in which the side-wall surface may have a positive trapezoidal shape inclined toward the inside of the lower anode electrode UAN as it moves upward. For example, the bottom surface of the first pixel defining layer PA1 may be in surface contact with the lower anode electrode UAN, and the side-wall surface and the top surface of the first pixel defining layer PA1 may be in surface contact with the anode electrode ANO. In one or more aspects, it is preferable that upper edge corners where the top surface and the side-wall surface meet are rounded or chamfered to have a curved shape.

When the upper edge corners may not have the rounded or chamfered shape, a sharply bent edge corners may be formed in the anode electrode ANO stacked thereon. In this case, the electric energy may be concentrated at the sharply bent portion formed on the edge corner of the anode electrode ANO, so that the emission layer EL deposited (or disposed) on the anode electrode ANO may be damaged or deteriorated.

By having upper edges of the first pixel defining layer PA1 have a rounded or chamfered shape, in one or more aspects, it is preferable to prevent sharp edges from occurring in cross-sectional profile of the anode electrode ANO. After that, forming the second pixel defining layer PA2, the entire top surface of the anode electrode ANO not covered by the second pixel defining layer PA2 may be defined as the emission area EA. This structure has the advantages of securing a wider emission area EA compared to the related structure in which the pixel defining layer covers part of the circumferential areas of the anode electrode.

In one or more examples, each of the first pixel defining layer PA1, the second pixel defining layer PA2, and the trench TR may be made of an insulating material, a dielectric material or a non-conductive material. In an example, the first pixel defining layer PA1, the second pixel defining layer PA2, and the trench TR may be made of the same material. In some examples, two or more of the first pixel defining layer PA1, the second pixel defining layer PA2, and the trench TR may be made of different materials. In one or more examples, the first pixel defining layer PA1, the second pixel defining layer PA2, and the trench TR are made of a material(s) that is different from a material(s) of the anode electrode ANO and the lower anode electrode UAN.

In one or more examples, a thickness of each of the first pixel defining layer PA1, the second pixel defining layer PA2, and the trench TR is greater than a thickness of the anode electrode ANO and is greater than a thickness of the lower anode electrode UAN.

### Second Example Embodiment

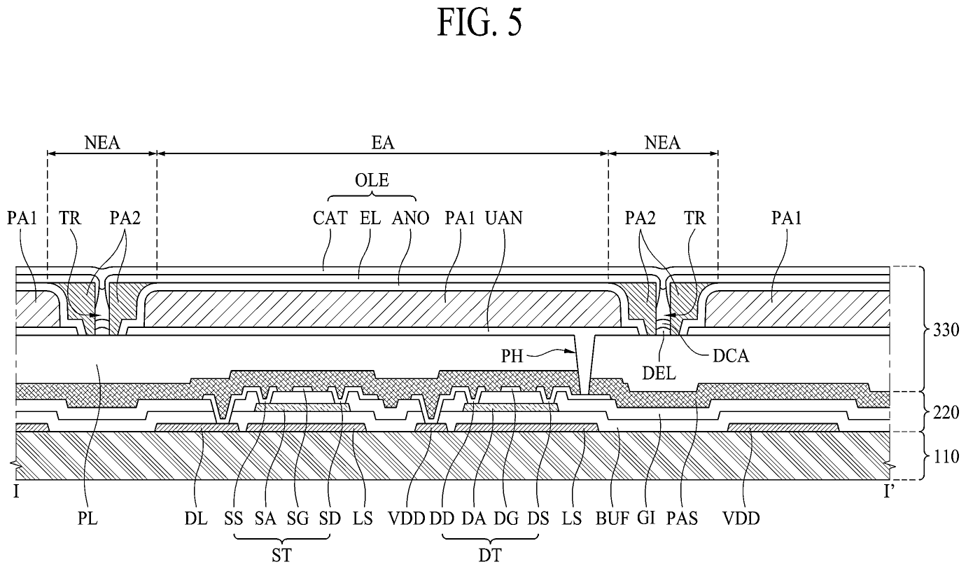

Referring to FIG. 5, a structure of a light emitting display device according to a second example embodiment of the present disclosure will be described. FIG. 5 is a cross-sectional view, along line I-I′ of FIG. 3, for illustrating a structure of a light emitting display device according to a second example embodiment of the present disclosure.

Referring to FIG. 5, the light emitting display device according to a second example embodiment of the present disclosure may have a very similar structure as the first example embodiment. In the second example embodiment, the area exposed by the first pixel defining layer PA1 of the lower anode electrode UAN is secured to be wider than that of the first example embodiment. Other components or features of FIG. 5 may be the same as or similar to the components or features of FIG. 4, and thus, the repetitive description thereof may be omitted for brevity.

In cases where the large diagonal length is 10 inches or less such as a display device for mobile devices, when the resolution increases, the pixel size may be very small, as described in the first example embodiment. In these cases, even when the contact area between the lower anode electrode UAN and the anode electrode ANO is not ensured enough, problems may not occur in the electrical connection between them.

However, in the case of display devices such as display devices larger than 17 inches or large TV monitor more than 40 inches, the size of a single pixel may be much larger than that of the mobile display device even though the resolution increases. In this case, when the contact area between the lower anode electrode UAN and the anode electrode ANO is small, problems may occur in the electrical connection between them.

Since the light emitting display device according to the second example embodiment is related to a top emission type display device, most of the area of the pixel P may be used as the emission area EA, so that a structure with a higher aperture ratio than the bottom emission type display area may be acquired. Therefore, even though the area of the lower anode electrode UAN that is not obscured by the first pixel defining layer PA1 becomes slightly larger, the aperture ratio may not decrease significantly. However, when there is a problem with the electrical connectivity between the lower anode electrode UAN and the anode electrode ANO, the pixel may become a defective pixel and cause quality problems. Therefore, in a display device in which the size of the pixel P is relatively large, in one or more aspects, it is preferable to ensure a larger contact area between the lower anode electrode UAN and the anode electrode ANO.

Referring to FIG. 5, the light emitting display device according to the second example embodiment may have a structure in which the first pixel defining layer PA1 may be formed at the most middle portions of the lower anode electrode UAN. The circumferential areas of the lower anode electrode UAN may be exposed by removing some portions of the first pixel defining layer PA1. After that, the anode electrode ANO is deposited and patterned. As a result, some surfaces of the anode electrode ANO and some surfaces of the lower anode electrode UAN may be in surface contact with each other at the circumferential areas, i.e., “surface contact”.

Here, the contact structure in which end portion of the anode electrode ANO corresponding to the thickness of the anode electrode ANO is in contact with the lower anode electrode UAN at the area where the anode electrode ANO is in contact with the lower anode electrode UAN as described in the first example embodiment may be referred to as an “end contact”.

On the contrary, the contact structure in which circumferential portions of the anode electrode ANO are bent and are in surface contact with the lower anode electrode UAN at the area where the anode electrode ANO is in contact with the lower anode electrode UAN as described in the second example embodiment may be referred to as a “surface contact”.

### Third Example Embodiment

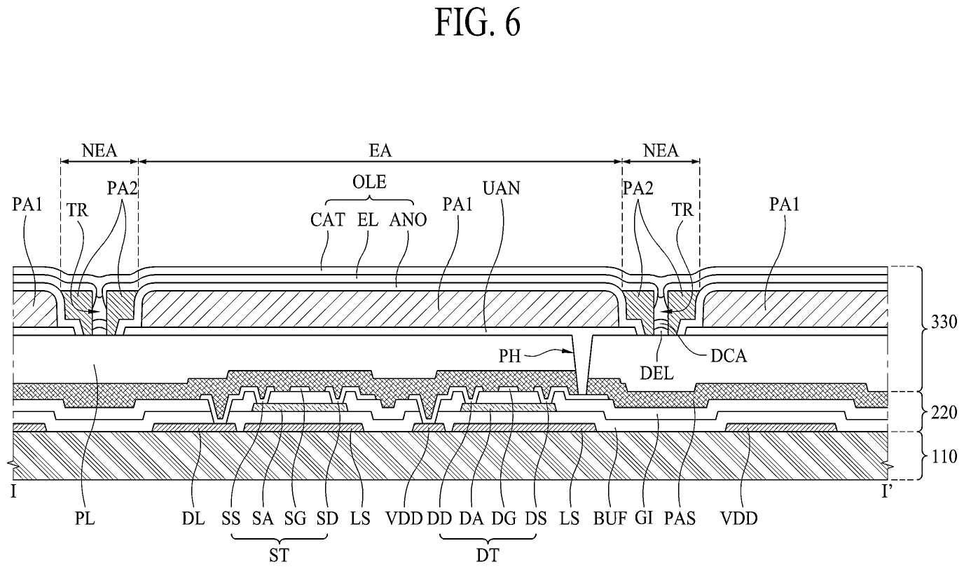

Referring to FIG. 6, a structure of a light emitting display device according to a third example embodiment of the present disclosure will be described. FIG. 6 is a cross-sectional view, along line I-I′ of FIG. 3, for illustrating a structure of a light emitting display device according to a third example embodiment of the present disclosure.

Referring to FIG. 6, the light emitting display device according to a third example embodiment of the present disclosure may have a very similar structure as the second example embodiment. In the third example embodiment, the height of the second pixel defining layer PA2 may be lower than the height of the top surface of the anode electrode ANO. Other components or features of FIG. 6 may be the same as or similar to the components or features of FIG. 5, and thus, the repetitive description thereof may be omitted for brevity.

The light emitting display device according to the third example embodiment may have a structural feature to prevent the aperture ratio from decreasing by maximally exposing the anode electrode ANO. According to the first example embodiment of the present disclosure, in one or more aspects, it is preferable to round or chamfer the upper edge corners of the first pixel defining layer PA1. When the rounding is not performed, the edge corners of the anode electrode ANO may have a sharp structure, and electric current may concentrate in these areas, causing the damage to the emitting layer EL.

When the first pixel defining layer PA1 and the anode electrode ANO have a rounded structure at the edge corners, as the top surface of the second pixel defining layer PA2 is formed to have the same plane as the top surface of the anode electrode ANO, the second pixel defining layer PA2 may cover edge portions of the top surface of the anode electrode ANO at the rounded portions. As a result, the aperture ratio may be degraded. However, in the third example embodiment in which the rounded edge corners are exposed by the second pixel defining layer PA2, the aperture ratio may not be degraded.

In one or more aspects, it is important that the relationship between the height of the top surface of the second pixel defining layer PA2 and the height of the top surface of the anode electrode ANO is optimized. When the height of the top surface of the second pixel defining layer PA2 is too low, the depth of the trench TR may be shallow. As a result, it may not be possible to establish a structure for breaking the continuity of the emission layer EL between neighboring pixels. Considering this situation, in one or more aspects, it is most preferable to arrange the height of the top surface of the second pixel defining layer PA2 at the same leveled plane as the height of the top surface of the first pixel defining layer PA1. To do so, it may have a structure in which the anode electrode ANO is exposed in all directions as much as the thickness of the anode electrode ANO in addition to the planar area of the anode electrode ANO.

In this case, it may have a structure that ensures the emission area EA as much as possible. Further, the maximum height of the second pixel defining layer PA2 that may ensure a sufficient depth of the trench TR may be simultaneously satisfied.

However, the present disclosure is not limited thereto. The height of the top surface of the second pixel defining layer PA2 may be set to be slightly lower than the height of the top surface of the first pixel defining layer PA1. Here, in one or more aspects, it is important to sufficiently consider the depth of the trench TR. For example, the height of the top surface of the second pixel defining layer PA2 may be set between 70% and 90% of the height of the first pixel defining layer PA1.

Further, in the case that the rounded circumferential area of the anode electrode ANO is included in the emission area EA as described in the third example embodiment, the light emitted from the circumferential area is emitted in a more diffused direction than the front direction. As the result, it has the effect that the viewing angle is expanded.

For example, in the structure shown in FIGS. 4 and 5, the front luminance may be very high, but the side luminance may be reduced due to a narrow viewing angle, so the image quality may be degraded due to luminance deviation at the wide viewing angle direction. However, in the third example embodiment shown in FIG. 6, the viewing angle may be enlarged, so it may provide excellent image quality without luminance deviation even at the wide viewing angle direction.

The third example embodiment is provided as a modified example based on the second example embodiment. However, it is not limited thereto, and the key feature of the third example embodiment may be applied to the first example embodiment.

### Fourth Example Embodiment

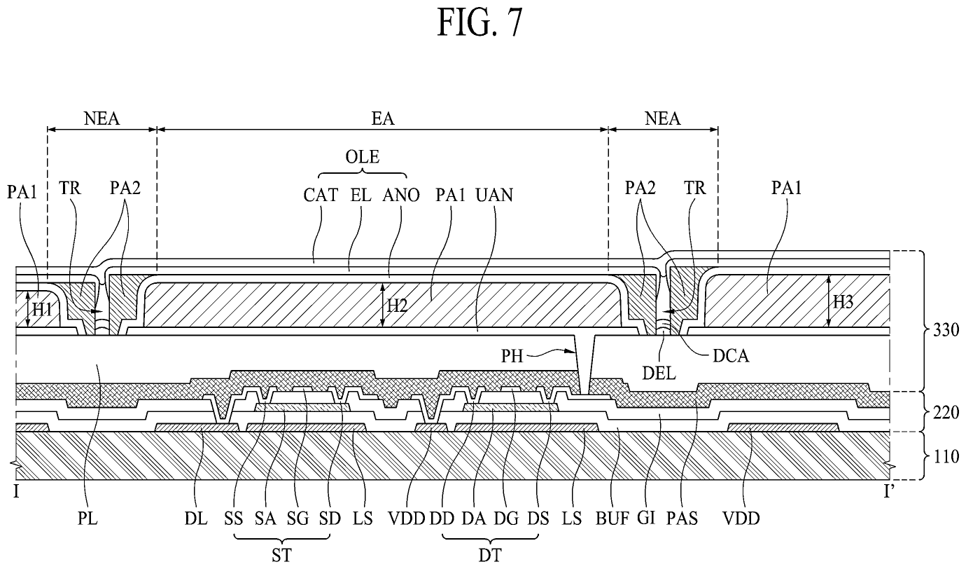

Referring to FIG. 7, a structure of a light emitting display device according to a fourth example embodiment of the present disclosure will be described. FIG. 7 is a cross-sectional view, along line I-I′ of FIG. 3, for illustrating a structure of a light emitting display device according to a fourth example embodiment of the present disclosure.

Referring to FIG. 7, a light emitting display device according to the fourth example embodiment may have a very similar structure as the second example embodiment. In the fourth example embodiment, the height of the first pixel defining layer PA1 is formed differently in each pixel P. Other components or features of FIG. 7 may be the same as or similar to the components or features of FIG. 5, and thus, the repetitive description thereof may be omitted for brevity.

For example, at a left pixel P1 in FIG. 7, the first pixel defining layer PA1 may have a first height H1. At a middle pixel P2, the first pixel defining layer PA1 may have a second height H2 higher than the first height H1. Further, at a right pixel P3, the first pixel defining layer PA1 may have a third height H3 higher than the second height H2.

The fourth example embodiment provides an example for establishing a micro-cavity structure to ensure maximum light extraction efficiency of the light in a specific wavelength range emitted from each pixel. For example, the first height H1, the second height H2 and the third height H3 may be appropriately adjusted to each pixel to satisfy the conditions for each micro-cavity in the pixel array structure having a red pixel, a green pixel and a blue pixel.

The fourth example embodiment is provided as a modified example based on the second example embodiment. However, it is not limited thereto, and the key feature of the fourth example embodiment may be applied to the third example embodiment.

In the above descriptions, the lower anode electrode UAN and the anode electrode ANO are described as components of the light emitting display device according to one or more example embodiments of the present disclosure. However, the present disclosure is not limited thereto. The anode electrode may be referred to as the upper anode electrode, and the lower anode electrode together with the upper anode electrode may be referred to as the anode electrode.

The features, structures, effects and so on described in the above example embodiments of the present disclosure are included in at least one example embodiment of the present disclosure, and are not necessarily limited to only one example embodiment. Furthermore, the features, structures, effects and the like explained in at least one example embodiment may be implemented in combination or modification with respect to other example embodiments by those skilled in the art to which this disclosure is directed. Accordingly, such combinations and variations should be construed as being included in the scope of the present disclosure.

It will be apparent to those skilled in the art that various substitutions, modifications, and variations are possible within the scope of the present disclosure without departing from the spirit and scope of the present disclosure. Therefore, it is intended that embodiments of the present disclosure cover the various substitutions, modifications, and variations of the present disclosure that come within the scope of the appended claims and their equivalents. These and other changes can be made to the embodiments in light of the above detailed description. In general, in the following claims, the terms used should not be construed to limit the claims to the specific example embodiments disclosed in the specification and the claims, but should be construed to include all possible embodiments along with the full scope of equivalents to which such claims are entitled. Accordingly, the claims are not limited by the disclosure.

What is claimed is:

1. A light emitting display device, comprising:
a lower anode electrode on a substrate;
a first pixel defining layer covering middle areas of the lower anode electrode and exposing circumferential areas of the lower anode electrode;
an anode electrode covering a top surface of the first pixel defining layer and connecting to the circumferential areas of the lower anode electrode;
a second pixel defining layer exposing a top surface of the anode electrode and covering a side-wall surface of the anode electrode;
a trench formed at the second pixel defining layer and disposed around the anode electrode;
an emission layer on the anode electrode; and
a cathode electrode on the emission layer.

2. The light emitting display device according to claim 1, wherein a top surface of the second pixel defining layer is disposed at a same leveled plane as the top surface of the anode electrode.

3. The light emitting display device according to claim 2, further comprising:
an emission area defined by portions of the anode electrode, the portions of the anode electrode being not covered by the second pixel defining layer.

4. The light emitting display device according to claim 1, wherein an end portion of the anode electrode is in contact with an end portion of the lower anode electrode.

5. The light emitting display device according to claim 1, wherein end portions of the anode electrode are bent to be in surface contact with circumferential top surfaces of the lower anode electrode.

6. The light emitting display device according to claim 1, wherein a top surface of the second pixel defining layer is disposed at a plane lower than the top surface of the anode electrode.

7. The light emitting display device according to claim 1, wherein a top surface of the second pixel defining layer is disposed at a plane same as the top surface of the anode electrode.

8. The light emitting display device according to claim 1, wherein a cross-sectional shape of the first pixel defining layer is a rectangular shape including:
a bottom surface being in surface contact with the lower anode electrode; and
the top surface and a side-wall surface being in surface contact with the anode electrode.

9. The light emitting display device according to claim 8, wherein:
the first pixel defining layer includes an upper edge corner; and
the upper edge corner has a curved shape where the top surface and the side-wall surface of the first pixel defining layer meet.

10. The light emitting display device according to claim 9, wherein the anode electrode is disposed on the first pixel defining layer, following the curved shape at the upper edge corner of the first pixel defining layer.

11. A light emitting display device, comprising:
a plurality of pixels on a substrate;
a plurality of anode electrodes, each of the plurality of anode electrodes disposed at a corresponding one of the plurality of pixels;
a first pixel defining layer between the plurality of anode electrodes;
a trench formed at a middle portion of the first pixel defining layer;
an emission layer disposed on the plurality of anode electrodes and the first pixel defining layer, the emission layer being separated between the plurality of anode electrodes by the trench; and
a cathode electrode disposed on the emission layer, the cathode electrode extending over all of the plurality of pixels and extending over the trench.

12. The light emitting display device according to claim 11, wherein a top surface of the first pixel defining layer is disposed at a plane same as a top surface of an anode electrode of the plurality of anode electrodes.

13. The light emitting display device according to claim 11, further comprising:
an emission area defined by an area of an anode electrode of the plurality of anode electrodes, the area being not covered by the first pixel defining layer.

14. The light emitting display device according to claim 11, wherein a top surface of the first pixel defining layer is disposed at a plane with a height lower than a top surface of an anode electrode of the plurality of anode electrodes by a thickness of the anode electrode.

15. The light emitting display device according to claim 11, wherein each of the plurality of anode electrodes includes:
a lower anode electrode;
a second pixel defining layer covering middle areas of the lower anode electrode and exposing circumferential areas of the lower anode electrode; and
an upper anode electrode covering a top surface of the second pixel defining layer and being in connection with the circumferential areas of the lower anode electrode exposed by the second pixel defining layer.

16. The light emitting display device according to claim 15, wherein a cross-sectional shape of the second pixel defining layer is a rectangular shape including:
a bottom surface being in surface contact with the lower anode electrode; and
the top surface and a side-wall surface being in surface contact with the upper anode electrode.

17. The light emitting display device according to claim 16, wherein:
the second pixel defining layer includes an upper edge corner; and
the upper edge corner has a curved shape where the top surface and the side-wall surface of the second pixel defining layer meet.

18. The light emitting display device according to claim 17, wherein the upper anode electrode is disposed on the second pixel defining layer, following the curved shape at the upper edge corner of the second pixel defining layer.

19. The light emitting display device according to claim 15, wherein the second pixel defining layer disposed at a first pixel of the plurality of pixels has a height different from a height of the second pixel defining layer disposed at another pixel of the plurality of pixels neighboring the first pixel.

20. A light emitting display device, comprising:
a lower anode electrode disposed on a substrate, the lower anode electrode having a central portion and a circumferential portion;
an upper anode electrode disposed on the lower anode electrode, the upper anode electrode being in contact with the circumferential portion of the lower anode electrode;
a first pixel defining layer disposed between the lower anode electrode and the upper anode electrode, the first pixel defining layer located at least at the central portion of the lower anode electrode without covering the circumferential portion of the lower anode electrode;
an emission layer on the upper anode electrode; and
a cathode electrode on the emission layer.

21. The light emitting display device according to claim 20, further comprising:
a second pixel defining layer surrounding the upper anode electrode; and
a trench surrounding the upper anode electrode.
